(19) United States
(12) Patent Application Publication
(10) Pub. No.: US 2026/0271373 A1
(43) Pub. Date: Sep. 10, 2026

(54) SEMICONDUCTOR DEVICE AND POWER CONVERSION DEVICE

(71) Applicant: Mitsubishi Electric Corporation, Chiyoda-ku, Tokyo (JP)

(72) Inventors: Keiji BEPPU, Tokyo (JP); Kazunari NAKATA, Tokyo (JP); Munenori IKEDA, Tokyo (JP)

(73) Assignee: Mitsubishi Electric Corporation, Chiyoda-ku, Tokyo (JP)

(21) Appl. No.: 19/167,828

(22) PCT Filed: Apr. 4, 2024
(86) PCT No.: PCT/JP2024/013976

§ 371 Date: Sep. 22, 2025

(30) Foreign Application Priority Data
Apr. 12, 2023 (JP) 2023-064655

(51) Int. Cl. H10D 84/00; H02P 27/08; H10D 62/832; H10D 64/27; H10D 84/01

(52) U.S. Cl. CPC H10D 84/146; H10D 62/8325; H10D 64/516; H10D 84/0109; H02P 27/08

(57) ABSTRACT

An object is to provide a technology that can enhance the reliability of a semiconductor device when operating. A dimension of a first portion of a first interlayer insulating film on a side of an opposite region with respect to a gate electrode is larger than a dimension of a second portion of the first interlayer insulating film on a side of an active region with respect to the gate electrode when a first heating value on the side of the opposite region is larger than a second heating value on the side of the active region, the opposite region being located opposite to the active region with respect to the gate electrode, and the dimension of the second portion is larger than the dimension of the first portion when the second heating value is larger than the first heating value.

### TECHNICAL FIELD

The present disclosure relates to a semiconductor device and a power conversion device.

### BACKGROUND ART

Semiconductor devices have found applications in power semiconductor devices made of silicon carbide (SiC) superior in breakdown voltage, low resistance, and heat resistance to silicon (Si) so that, for example, the semiconductor devices can increase the breakdown voltage, reduce losses, and be used under high-temperature environments. Known power semiconductor devices include a metal-oxide semiconductor field-effect transistor (MOSFET) and an insulated-gate bipolar transistor (IGBT). For example, a MOSFET made of SiC at 1 to 1.2 kV breakdown voltage level can have a ON resistance of 2 mΩ cm² or lower, and can have a resistance value less than or equal to half a resistance value of a MOSFET and an IGBT made of Si with the same breakdown voltage. Conceivable reasons why ON resistances of SiC semiconductor devices can be reduced more significantly than those of Si semiconductor devices are that the SiC semiconductor devices have higher dielectric breakdown field, can make breakdown voltage layers (i.e., drift layers) for implementing the breakdown voltages thinner than those of Si semiconductor devices, and increase the impurity doping amounts of the breakdown voltage layers.

Semiconductor devices can be downsized by increasing a current density at which a current is passed through a semiconductor device, and the manufacturing cost of the semiconductor devices can be reduced by using parasitic diodes in MOSFET. In view of these, semiconductor devices made of SiC will become the mainstream of inverter components from now on.

Continuously passing a forward current, specifically, a bipolar current through a SiC p-n diode, however, increases recombined energy obtained when minority carriers injected in passing the current through the p-n diode are recombined with majority carriers. This consequently expands stacking faults that are plane defects, starting from, for example, basal plane dislocations in a SiC substrate. Since expansion of stacking faults reduces the current and increases the forward current, that is, shifts the forward current, this causes a reliability problem, that is, a decrease in reliability of a semiconductor device.

Various technologies have been proposed to suppress the decrease in reliability in passing the forward current through the parasitic p-n diode as described above. For example, Patent Document 1 proposes providing a p⁺ type semiconductor region that is a hole-extracting region to surround an active region including MOSFETs, in a semiconductor substrate including an n-type SiC substrate and an epitaxial growth layer on the SiC substrate. Furthermore, Patent Documents 2 and 3 propose embedding a Schottky barrier diode (SBD) as a unipolar diode in a semiconductor chip corresponding to a MOSFET.

### PRIOR ART DOCUMENT

### Patent Document

[Patent Document 1] Japanese Patent Application Laid-Open No. 2019-75411

[Patent Document 2] Japanese U.S. Pat. No. 7,078,226

[Patent Document 3] Japanese U.S. Pat. No. 7,170,781

### SUMMARY

### Problem to be Solved by the Invention

Downsizing a semiconductor device and increasing the efficiency thereof, however, increase the current density at which a current is passed through the semiconductor device and increase the operating temperature. When thermal stresses caused by this temperature increase are intensified, problems occur, that is, a gate electrode in a termination region is more easily damaged, and the reliability of the semiconductor device is impaired.

Thus, the present disclosure has been made in view of the problems, and has an object of providing a technology that can enhance the reliability of the semiconductor device when operating.

### Means to Solve the Problem

A semiconductor device according to the present disclosure is a semiconductor device in which an active region and a termination region are defined, the semiconductor device including: a first interlayer insulating film provided in the termination region; and a gate electrode provided on the first interlayer insulating film, wherein a dimension of a first portion of the first interlayer insulating film on a side of an opposite region with respect to the gate electrode is larger than a dimension of a second portion of the first interlayer insulating film on a side of the active region with respect to the gate electrode when a first heating value on the side of the opposite region is larger than a second heating value on the side of the active region, the opposite region being located opposite to the active region with respect to the gate electrode, and the dimension of the second portion is larger than the dimension of the first portion when the second heating value is larger than the first heating value.

### Effects of the Invention

According to the present disclosure, the dimension of the first portion is larger than the dimension of the second portion when the first heating value is larger than the second heating value, and the dimension of the second portion is larger than the dimension of the first portion when the second heating value is larger than the first heating value. With such a structure, the reliability of the semiconductor device when operating can be enhanced.

### BRIEF DESCRIPTION OF DRAWINGS

FIG. 1 is a top view illustrating a structure of a semiconductor device according to Embodiment 1.

FIG. 2 is a top view illustrating a structure of the semiconductor device according to Embodiment 1.

FIG. 3 is a cross-sectional schematic diagram illustrating the structure of the semiconductor device according to Embodiment 1.

FIG. 4 is a flowchart illustrating a method of manufacturing the semiconductor device according to Embodiment 1.

FIG. 5 is a cross-sectional schematic diagram illustrating a step for manufacturing the semiconductor device according to Embodiment 1.

FIG. 6 is a cross-sectional schematic diagram illustrating a step for manufacturing the semiconductor device according to Embodiment 1.

FIG. 7 is a cross-sectional schematic diagram illustrating a step for manufacturing the semiconductor device according to Embodiment 1.

FIG. 8 is a cross-sectional schematic diagram illustrating a step for manufacturing the semiconductor device according to Embodiment 1.

FIG. 9 is a cross-sectional schematic diagram illustrating a step for manufacturing the semiconductor device according to Embodiment 1.

FIG. 10 is a cross-sectional schematic diagram illustrating a step for manufacturing the semiconductor device according to Embodiment 1.

FIG. 11 is a cross-sectional schematic diagram illustrating a step for manufacturing the semiconductor device according to Embodiment 1.

FIG. 12 is a cross-sectional schematic diagram illustrating a step for manufacturing the semiconductor device according to Embodiment 1.

FIG. 13 is a cross-sectional schematic diagram illustrating a step for manufacturing the semiconductor device according to Embodiment 1.

FIG. 14 is a cross-sectional schematic diagram illustrating a step for manufacturing the semiconductor device according to Embodiment 1.

FIG. 15 is a cross-sectional schematic diagram illustrating a step for manufacturing the semiconductor device according to Embodiment 1.

FIG. 16 is a cross-sectional schematic diagram illustrating a step for manufacturing the semiconductor device according to Embodiment 1.

FIG. 17 is a cross-sectional schematic diagram and a SEM photograph which illustrate the structure of the semiconductor device according to Embodiment 1.

FIG. 18 is a diagram illustrating a result of a trial calculation of thermal stresses applied to a gate electrode in the semiconductor device according to Embodiment 1.

FIG. 19 is a cross-sectional schematic diagram illustrating a structure of a semiconductor device according to Modification 1 of Embodiment 1.

FIG. 20 is a cross-sectional schematic diagram illustrating a structure of a semiconductor device according to Modification 4 of Embodiment 1.

FIG. 21 is a top view illustrating a structure of a semiconductor device according to Embodiment 2.

FIG. 22 is a top view illustrating the structure of the semiconductor device according to Embodiment 2.

FIG. 23 is a flowchart illustrating a method of manufacturing the semiconductor device according to Embodiment 2.

FIG. 24 is a cross-sectional schematic diagram illustrating a structure of a semiconductor device according to Embodiment 3.

FIG. 25 is a top view illustrating a structure of a semiconductor device according to Embodiment 4.

FIG. 26 is a cross-sectional schematic diagram illustrating a structure of the semiconductor device according to Embodiment 4.

FIG. 27 is a flowchart illustrating a method of manufacturing the semiconductor device according to Embodiment 4.

FIG. 28 is a cross-sectional schematic diagram illustrating a structure of a semiconductor device according to Modification 1 of Embodiment 4.

FIG. 29 is a block diagram illustrating a configuration of a power conversion system to which a power conversion device according to Embodiment 5 is applied.

### DESCRIPTION OF EMBODIMENTS

Embodiments will be described with reference to the attached drawings. The features to be described in Embodiments below are exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up” or “down” need not always coincide with an actual position and an actual direction. A portion higher in concentration than another portion means that, for example, an average of concentrations in the portion is higher than an average of concentrations in the other portion. Conversely, a portion lower in concentration than another portion means that, for example, an average of concentrations in the portion is lower than an average of concentrations in the other portion.

### Embodiment 1

An example where a semiconductor device according to Embodiment 1 is a power semiconductor device, includes an n-type SiC substrate, and is a planar-gate metal-oxide semiconductor field-effect transistor (MOSFET) embedding a Schottky barrier diode (SBD) will be described. The semiconductor device is not limited to this but may be, for example, a trench-gate semiconductor device, an insulated-gate bipolar transistor (IGBT), or a reverse-conducting IGBT (RC-IGBT).

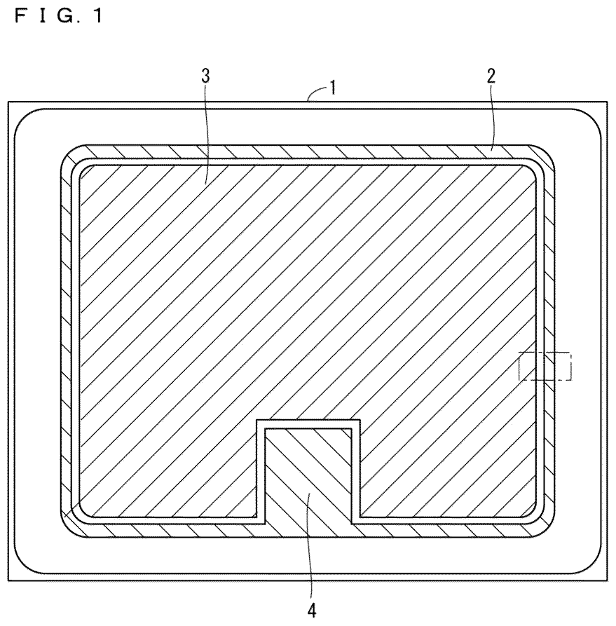

FIG. 1 is a top view illustrating a structure of a semiconductor device 1 according to Embodiment 1. On the top of the semiconductor device 1, a source electrode 3 located in a center portion, and a gate wire 2 surrounding the source electrode 3 are provided. Furthermore, a gate pad 4 is provided between a center and an end of an upper portion of the semiconductor device 1 to be electrically continuous to the gate wire 2. The gate wire 2 and the gate pad 4 are spaced and insulated from the source electrode 3. In this Description, a region in which unit cells are periodically arranged is defined as an active region, and a region other than the active region is defined as a termination region.

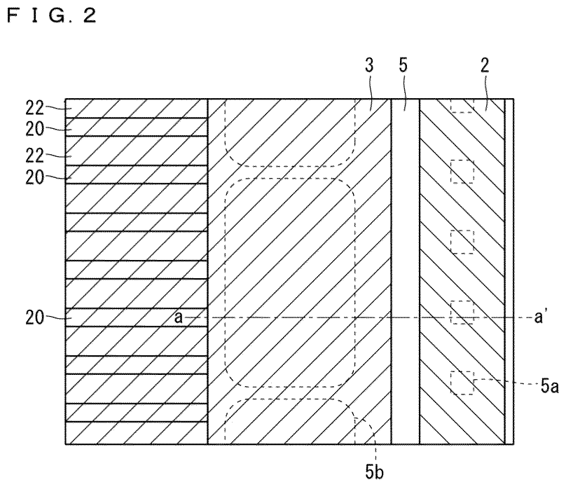

FIG. 2 is a top view illustrating an enlarged view of a portion between the active region and the termination region which is indicated by an alternate long and short dashed line in FIG. 1. In Embodiment 1, the active region includes SBD regions 20 provided with an SBD, and MOS regions 22 provided with a MOSFET. As illustrated in FIG. 2, a plurality of the SBD regions 20 are arranged periodically in stripes, a plurality of the MOS regions 22 are arranged periodically in stripes, and the SBD regions 20 and the MOS regions 22 are alternately arranged one by one.

A second interlayer insulating film 5 is disposed in a region other than the active region including the SBD regions 20 and the MOS regions 22, that is, in the termination region. The gate wire 2 and the source electrode 3 are disposed on the second interlayer insulating film 5. The second interlayer insulating film 5 has gate contact holes 5a covered with the gate wire 2, and contact holes 5b covered with the source electrode 3. As will be described later, an SBD is provided below the contact holes 5b in the termination region, similarly to the SBD regions 20 in the active region.

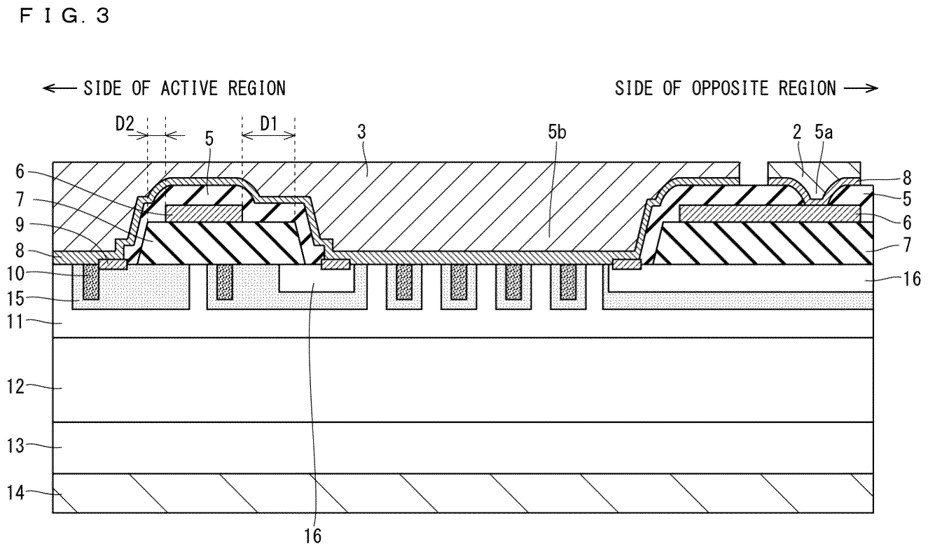

FIG. 3 is a cross-sectional schematic diagram illustrating a structure of a portion taken along an a-a′ line in FIG. 2. Since the second interlayer insulating film 5 is disposed in the termination region as described above, FIG. 3 mostly illustrates the structure of the termination region. Since the a-a′ line in FIG. 2 extends across the contact hole 5b of the second interlayer insulating film 5, FIG. 3 illustrates the second interlayer insulating film 5 in two portions that sandwich the contact hole 5b.

As illustrated in FIG. 3, the semiconductor device 1 according to Embodiment 1 includes, in the termination region, an n-type SiC substrate 13, an n-type epitaxial growth layer 12, an n-type well region 11, a p-type well region 15, p-type potential fixed layers 10, n-type source regions 16, contact regions 9, a first interlayer insulating film 7, a gate electrode 6, the second interlayer insulating film 5, a barrier metal layer 8, the source electrode 3, the gate wire 2, and a drain electrode 14.

The epitaxial growth layer 12 is uniformly provided on a first main surface (an upper surface in FIG. 3) of the SiC substrate 13, and the n-type well region 11 is provided on the epitaxial growth layer 12. Although a portion including the SiC substrate 13, the epitaxial growth layer 12, and the n-type well region 11 is a combination of an SiC substrate and an epitaxial growth layer in Embodiment 1, the portion may only consist of an SiC substrate or an epitaxial growth layer.

The p-type well region 15 is selectively provided on the top of the n-type well region 11. A side portion and a lower portion of each of the p-type potential fixed layers 10 are covered with the p-type well region 15, and a side portion and a lower portion of each of the source regions 16 are covered with the p-type well region 15.

The first interlayer insulating film 7 is selectively provided on the potential fixed layers 10, the n-type well region 11, the p-type well region 15, and the source regions 16 in the termination region. Since the first interlayer insulating film 7 has the contact holes 5b similarly to the second interlayer insulating film 5, FIG. 3 illustrates the first interlayer insulating film 7 in two portions similarly to the second interlayer insulating film 5.

The gate electrode 6 is provided on the first interlayer insulating film 7. In the two portions of the first interlayer insulating film 7 illustrated in FIG. 3, a region opposite to the active region with respect to the gate electrode 6 provided on the first interlayer insulating film 7 on the side of the active region will be referred to as an opposite region and described hereinafter.

The gate electrode 6 is electrically connected to a gate electrode (not illustrated) provided on the MOS regions 22 in FIG. 2, and has a potential identical to that of the gate electrode on the MOS regions 22. When a voltage higher than or equal to a threshold voltage is applied to the gate electrode on the MOS regions 22, a conductivity type of a portion of a p-type semiconductor layer sandwiched between n-type semiconductor layers is inverted, and a channel is formed in the portion. Since the structure of FIG. 3 is not directed to the MOS regions 22, the gate electrode 6 in FIG. 3 forms a channel in the p-type semiconductor layer indirectly in the MOS region, but does not form a channel directly in the p-type semiconductor layer in FIG. 3.

The second interlayer insulating film 5 is provided to cover the gate electrode 6 and the first interlayer insulating film 7. The second interlayer insulating film 5 has the gate contact holes 5a partially exposing the gate electrode 6 provided on the first interlayer insulating film 7 on a side of the opposite region, and the contact holes 5b partially exposing the n-type well region 11 in the termination region.

The barrier metal layers 8 cover the p-type potential fixed layers 10, the n-type well region 11, the p-type well region 15, the source regions 16, the second interlayer insulating film 5, and the gate electrode 6 exposed from the gate contact holes 5a. The barrier metal layer 8 covering the gate electrode 6 is spaced and insulated from the barrier metal layer 8 covering, for example, the n-type well region 11.

The contact region 9 is provided between the barrier metal layer 8 and one of the source regions 16, the p-type well region 15, and the p-type potential fixed layers 10 on the side of the active region with respect to the first interlayer insulating film 7, and ohmic connects these.

The contact region 9 is not provided between the barrier metal layer 8 and the n-type well region 11 in the contact holes 5b. The n-type well region 11 is Schottky-connected to the barrier metal layer 8. Thus, the SBD is provided below the contact holes 5b, similarly to the SBD regions 20 in the active region in FIG. 2.

The gate wire 2 is electrically continuous to the gate electrode 6 through the barrier metal layer 8 covering the gate electrode 6 exposed from the gate contact holes 5a. The source electrode 3 is electrically continuous to, for example, the n-type well region 11 through the barrier metal layer 8 covering, for example, the n-type well region 11. The drain electrode 14 is provided on a second main surface (a bottom surface in FIG. 3) opposite to the first main surface in which the epitaxial growth layer 12 on the SiC substrate 13 is provided.

Here, the SBD provided for the SBD regions 20 in the active region and the SBD provided below the contact holes 5b on the side of the opposite region generate heat when operating. In Embodiment 1, a first heating value on the side of the opposite region is configured to be larger than a second heating value on a side of the active region. Regarding the first interlayer insulating film 7 that is an interlayer insulating film on the side of the active region, a dimension of a first portion of the first interlayer insulating film 7 on the side of the opposite region with respect to the gate electrode 6 is larger than a dimension of a second portion of the first interlayer insulating film 7 on the side of the active region with respect to the gate electrode 6. For example, assuming that D1 denotes a distance between an end of an upper portion of the first portion on the side of the opposite region and an end of the gate electrode 6 on the side of the opposite region, and D2 denotes a distance between an end of an upper portion of the second portion on the side of the active region and an end of the gate electrode 6 on the side of the active region, the gate electrode 6 is biased toward the side of the active region with respect to the first interlayer insulating film 7 such that D1>0, D2>0, and D1-D2>0 hold. This will be described later in detail.

### Manufacturing Method

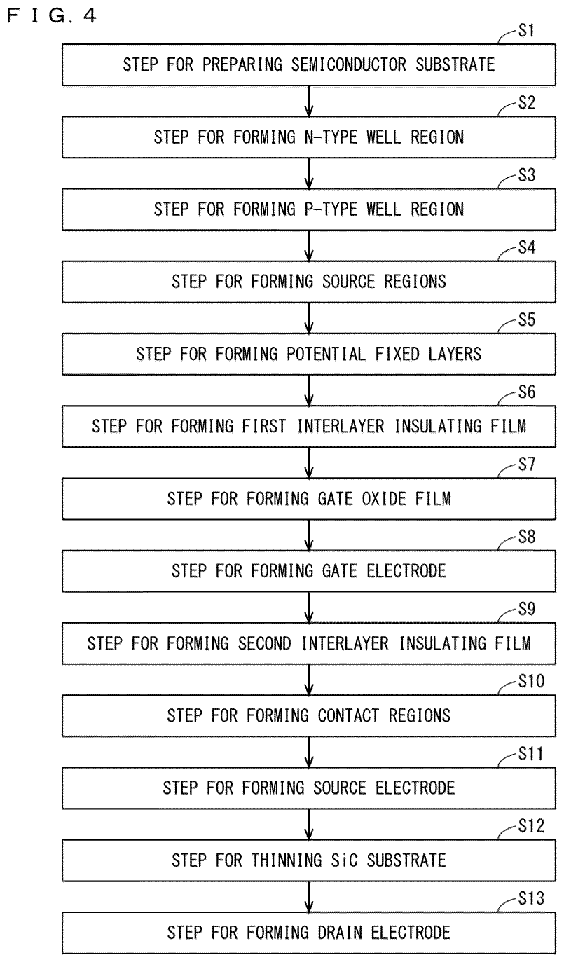

FIG. 4 is a flowchart illustrating a method of manufacturing the semiconductor device according to Embodiment 1. Hereinafter, each of Step S1 for preparing a semiconductor substrate to Step S13 for forming a drain electrode will be described.

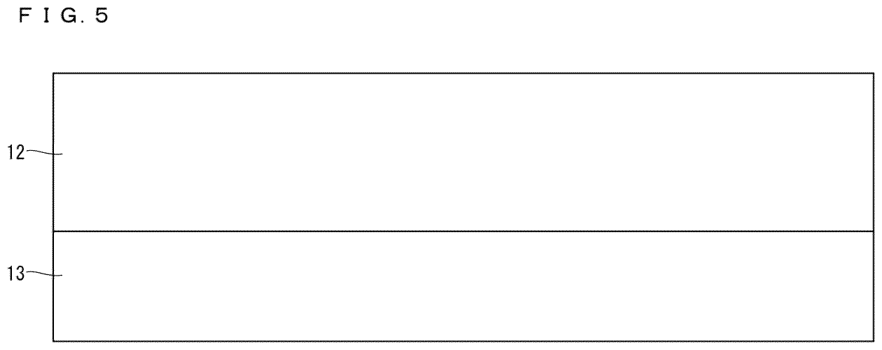

First, in Step S1 for preparing the semiconductor substrate, the epitaxial growth layer 12 made of n-type SiC is formed on the first main surface of the n-type SiC substrate 13 of a 4H polytype by chemical vapor deposition (CVD) as illustrated in FIG. 5. The n-type impurity concentration of the epitaxial growth layer 12 ranges, for example, from 1×10¹⁵ cm⁻³ to 1×10¹⁷ cm⁻³. Furthermore, the thickness of the epitaxial growth layer 12 ranges, for example, from 5 μm to 50 μm.

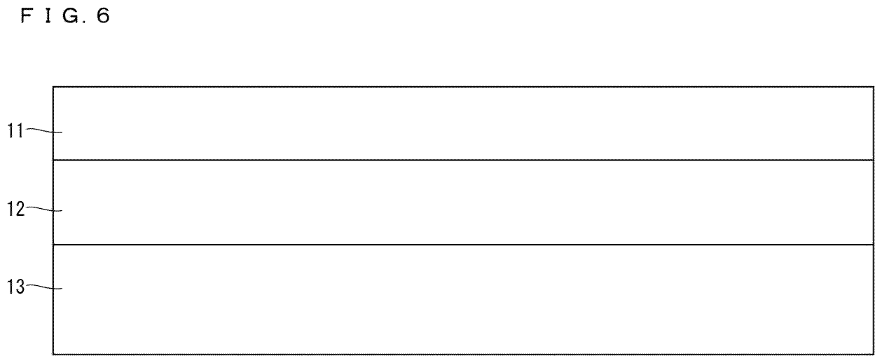

Next, in Step S2 for forming an n-type well region, impurities are ion-implanted on the top of the epitaxial growth layer 12 to form the n-type well region 11 as illustrated in FIG. 6. The impurity concentration of the n-type well region 11 is higher than that of the epitaxial growth layer 12.

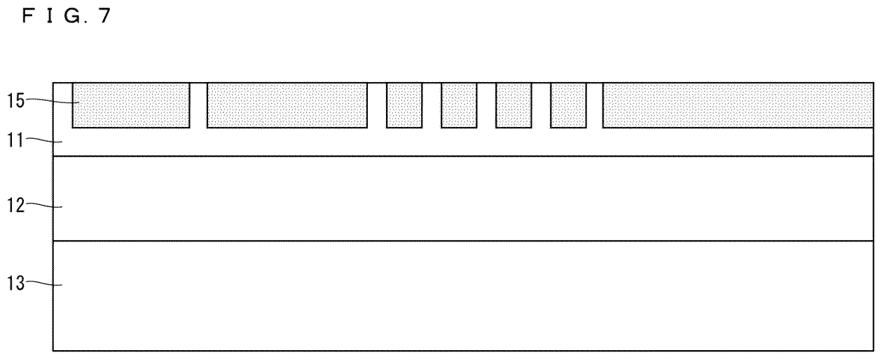

Then, in Step S3 for forming a p-type well region, an implantation mask is formed in a predefined region of the n-type well region 11 using, for example, a photoresist, and then, p-type impurities are ion-implanted to form the p-type well region 15 as illustrated in FIG. 7. Examples of the p-type impurities include boron (B) and aluminum (Al). A depth of implantation into the p-type well region 15 is less than a depth of the n-type well region 11. Furthermore, the impurity concentration of the p-type well region 15 ranges, for example, from 1×10¹⁷ cm⁻³ to 1×10¹⁹ cm⁻³.

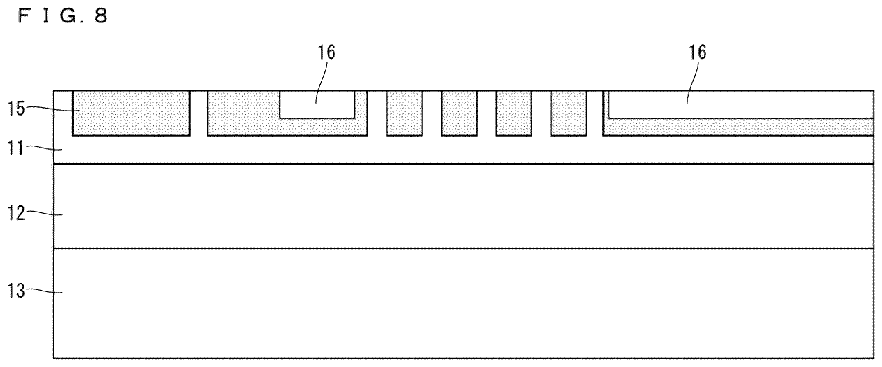

Then, in Step S4 for forming source regions, an implantation mask is formed in a predefined region of the p-type well region 15 using, for example, a photoresist, and then, n-type impurities are ion-implanted to form the source regions 16 as illustrated in FIG. 8. Examples of the n-type impurities include phosphorus and nitrogen. A depth of implantation into the source regions 16 is less than a depth of the p-type well region 15.

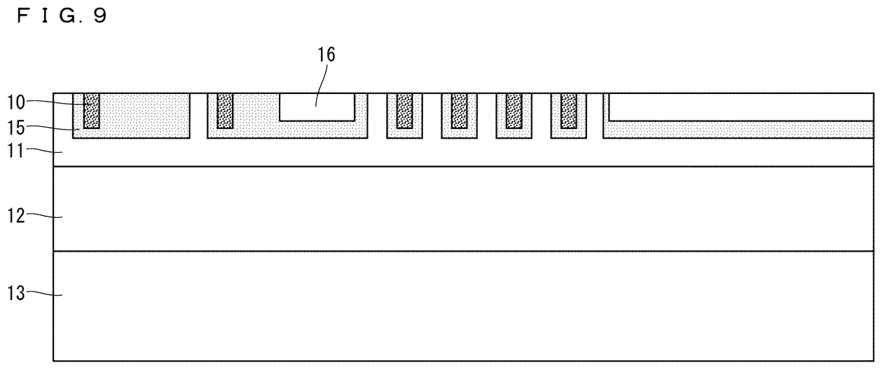

Then, in Step S5 for forming potential fixed layers, an implantation mask is formed in a predefined region of the p-type well region 15 using, for example, a photoresist, and then, p-type impurities are ion-implanted to form the potential fixed layers 10 as illustrated in FIG. 9. The impurity concentration of the potential fixed layers 10 is higher than that of the p-type well region 15. Next, a heat treatment apparatus anneals a structure obtained in the step illustrated in FIG. 9 at a temperature ranging from 1300 to 1900° C. in an inert gas atmosphere such as argon (Ar) gas for 30 seconds to 1 hour. This annealing electrically activates the implanted p-type and n-type impurities.

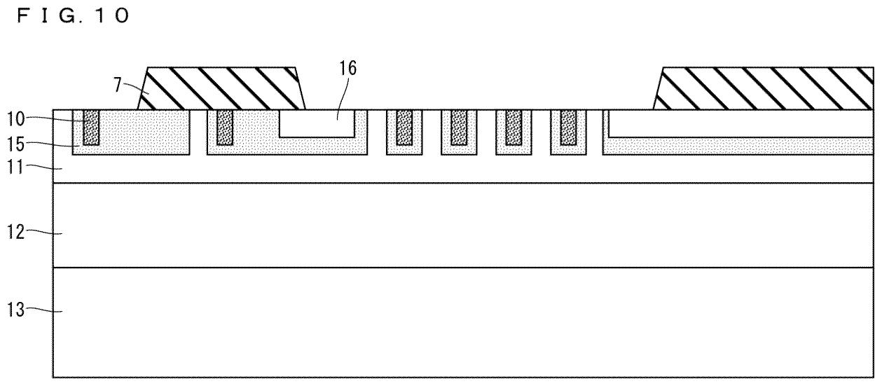

Then, in Step S6 for forming the first interlayer insulating film, an insulating film to be the first interlayer insulating film 7 is formed by CVD, and then, the insulating film is patterned using a photolithography technique and a dry or wet etching technique. This forms the first interlayer insulating film 7 remaining in a predefined region on the potential fixed layers 10, the n-type well region 11, the p-type well region 15, and the source regions 16 as illustrated in FIG. 10. Example materials of the first interlayer insulating film 7 include tetra ethoxy silane (TEOS).

Then, in Step S7 for forming a gate oxide film, a gate oxide film that is not illustrated is formed in the active region.

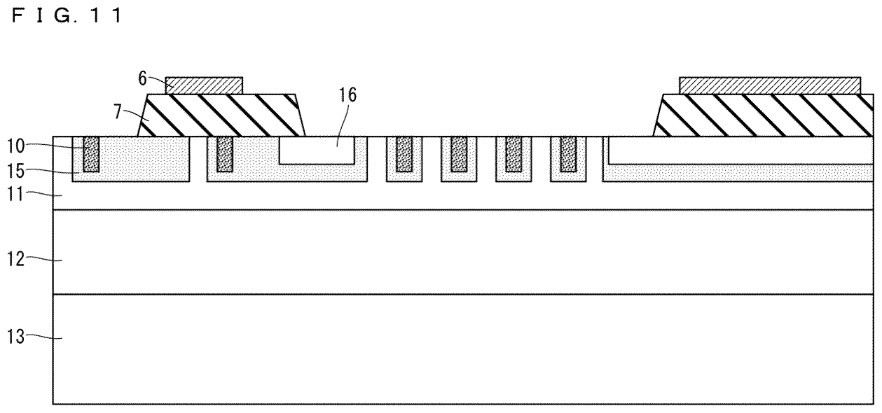

Next, in Step S8 for forming a gate electrode, a conductive film is deposited on, for example, the first interlayer insulating film 7 by thermal oxidation or CVD, and then, the conductive film is patterned using the photolithography technique and the dry or wet etching technique. This forms the gate electrode 6 including a portion biased toward the side of the active region with respect to the first interlayer insulating film 7 as illustrated in FIG. 11. Example materials of the conductive film to be the gate electrode 6 may include polycrystalline Si or poly-Si to be deposited using chemical vapor deposition, etc., and tungsten or tungsten silicide (WSiₓ) when the semiconductor device 1 performs operations at higher speeds.

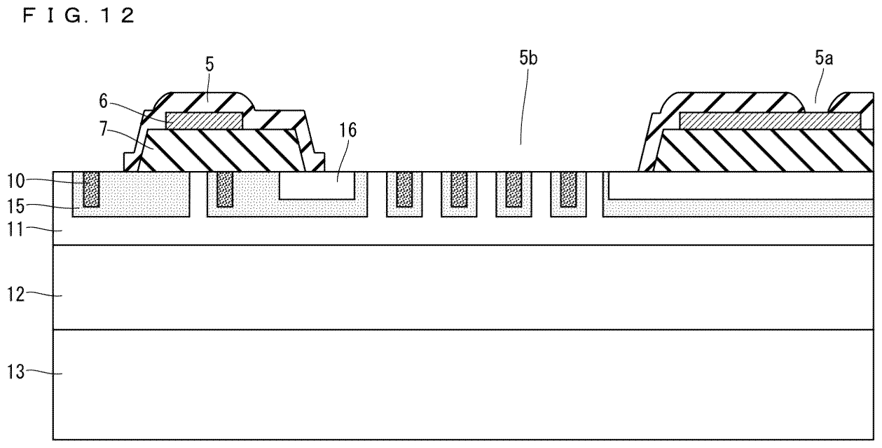

Then, in Step S9 for forming the second interlayer insulating film, an insulating film to be the second interlayer insulating film 5 is formed by CVD, and then, the insulating film is patterned using the photolithography technique and the dry or wet etching technique. This forms the second interlayer insulating film 5 that covers the gate electrode 6 and the first interlayer insulating film 7 and has the gate contact hole 5a and the contact hole 5b as illustrated in FIG. 12. Example materials of the second interlayer insulating film 5 include tetra ethoxy silane (TEOS) and borophosphosilicate glass (BPSG).

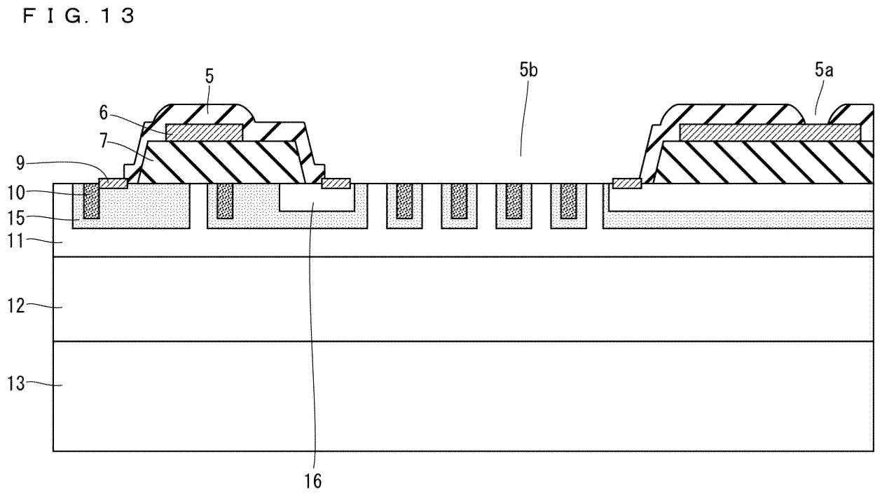

Next, in Step S10 for forming contact regions, the contact regions 9 are formed as illustrated in FIG. 13. Each of the contact regions 9 is, for example, a silicide layer formed by depositing a metal film containing nickel (Ni) as a main component, on an opening in, for example, the photoresist and subjecting the metal film to a thermal process at a temperature ranging from 600 to 1100° C.

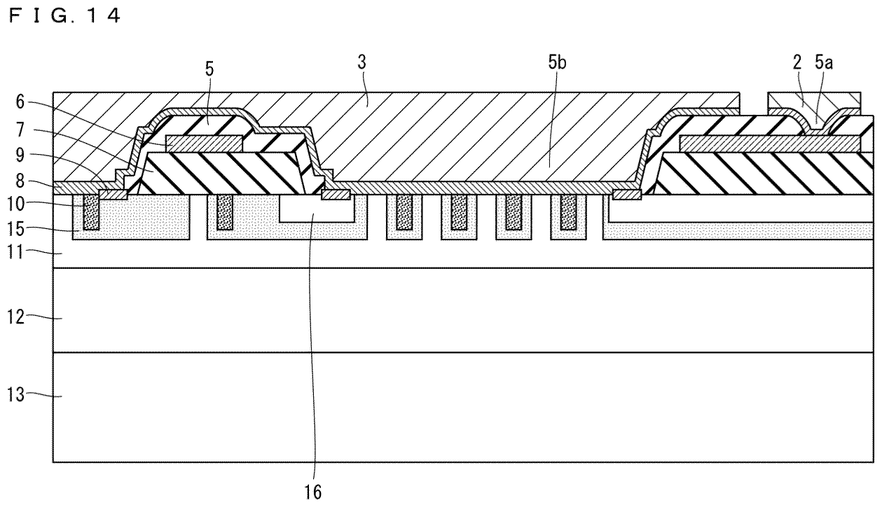

Next, in Step S11 for forming a source electrode, the barrier metal layer 8 made of titanium or a titanium compound such as or titanium nitride (TiN) is formed as illustrated in FIG. 14. Then, depositing, for example, one of aluminum and an aluminum alloy of aluminum and silicon, or nickel forms the gate wire 2 and the source electrode 3.

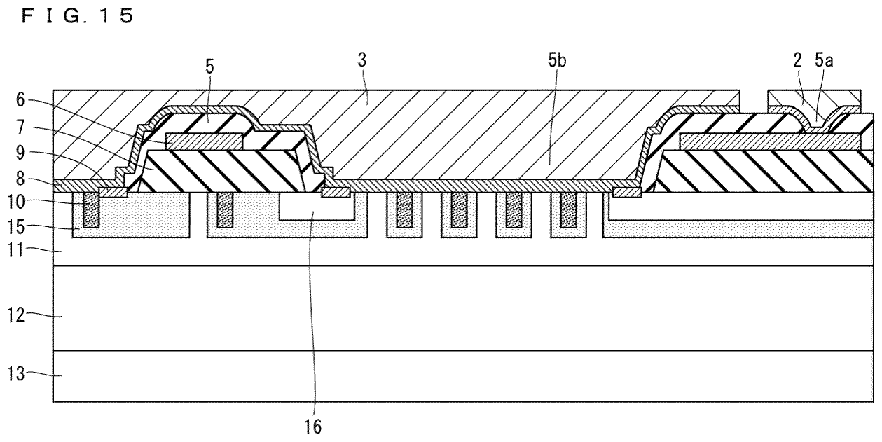

Then, in Step S12 for thinning an SiC substrate, machining the second main surface of the SiC substrate 13 using a grinding wheel makes the SiC substrate 13 thinner and leaner as illustrated in FIG. 15.

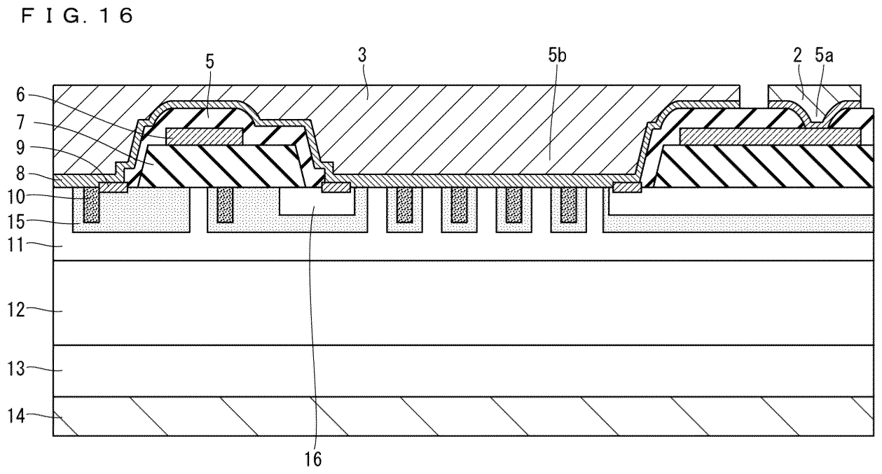

Next, in Step S13 for forming a drain electrode, depositing, for example, a nickel film of approximately 600 nm on the machined second main surface appropriately using sputtering, etc., forms the drain electrode 14 as illustrated in FIG. 16. When the front most surface of the nickel film is oxidized, the wettability of a solder alloy on the nickel film is worsened, and a bonding state in bonding chips is worsened. Thus, a film containing a metal that is less reactive to an outside such as gold (Au) and silver (Ag) may be formed on the front surface of the nickel film as a protective film. In other words, the drain electrode 14 may be a laminated film of the nickel film and the protective film.

### Summary of Embodiment 1

Since a current normally flows through a body diode (BD) region and an SBD region during a freewheeling operation in a semiconductor device such as a power semiconductor device, the semiconductor device itself generates heat due to resistive components of these currents. In a semiconductor device having, in a termination region, a region for allowing a current to flow in a freewheeling operation, heat is generated even in the termination region. In particular, a heating value of the termination region in a semiconductor device in which a current actively flows through an SBD below the contact holes 5b in the termination region is relatively larger, as in the semiconductor device according to Embodiment 1.

Here, since thermal expansion coefficients of the first interlayer insulating film 7 and the second interlayer insulating film 5 differ from that of the source electrode 3, thermal stresses caused by these occur in an interface between each of the interlayer insulating films and the source electrode 3. Thus, these thermal stresses cause problems in that the interlayer insulating films deteriorate, the insulation performance of the interlayer insulating films decreases, the gate electrode 6 in the termination region is damaged, and the semiconductor device malfunctions.

Furthermore, in a structure in which a semiconductor device is assembled into a power module or a discrete package, the semiconductor device is generally sealed by a sealant such as a resin or gel. Since a thermal expansion coefficient of the semiconductor device differs from that of the sealant in contact with the semiconductor device, thermal stresses caused by these create the similar problems above.

Thus, when the first heating value on the side of the opposite region is larger than the second heating value on the side of the active region in Embodiment 1, the dimension of the first portion of the first interlayer insulating film 7 on the side of the opposite region with respect to the gate electrode 6 is larger than the dimension of the second portion of the first interlayer insulating film 7 on the side of the active region with respect to the gate electrode 6.

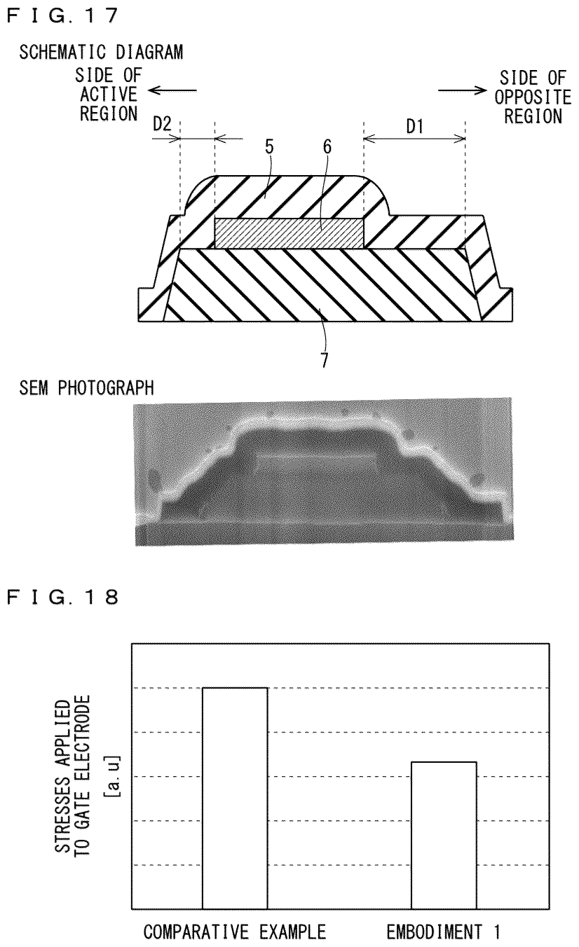

As the example, assuming that DI denotes the distance between the end of the upper portion of the first portion on the side of the opposite region and the end of the gate electrode 6 on the side of the opposite region, and D2 denotes the distance between the end of the upper portion of the second portion on the side of the active region and the end of the gate electrode 6 on the side of the active region as illustrated in the schematic diagram in FIG. 17, the gate electrode 6 is biased toward the side of the active region with respect to the first interlayer insulating film 7 such that D1>0, D2>0, and D1−D2>0 hold. The SEM photograph in FIG. 17 is an image of the semiconductor device manufactured by the manufacturing method according to Embodiment 1 and captured by a scanning electron microscope (SEM). In the SEM photograph of the semiconductor device, D1 is 17 approximately 1 μm, and D2 is approximately 0.5 μm.

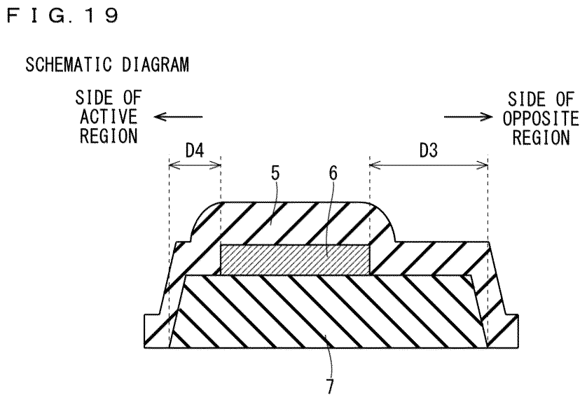

FIG. 18 is a diagram illustrating a result of a trial calculation of the thermal stresses applied to the gate electrode 6 in the semiconductor device according to Embodiment 1. The semiconductor device according to Embodiment 1 where D1−D2>0 holds can reduce the thermal stresses applied to the gate electrode 6 approximately by 30% when compared with a semiconductor device (a comparative example) where D2−D1>0 holds. Thus, since the semiconductor device according to Embodiment 1 can reduce the thermal stresses applied to the gate electrode 6 and suppress damage of the gate electrode 6, the reliability of the semiconductor device when operating can be enhanced.

In particular, a wide bandgap semiconductor device which is to be downsized more and whose efficiency is to be increased more by taking advantage of higher dielectric breakdown field of a wide bandgap semiconductor undergoes a significant increase in operating temperature. Thus, enhancing the reliability of the semiconductor device as described above is effective. Examples of the wide bandgap semiconductor include silicon carbide (SiC), gallium nitride (GaN), and diamond.

### Modification 1

FIG. 19 is a cross-sectional schematic diagram illustrating a structure of a semiconductor device according to Modification 1 of Embodiment 1. FIG. 19 illustrates D3 and D4. D3 denotes a distance between an end of the first portion on the side of the opposite region and an end of the gate electrode 6 on the side of the opposite region in a plan view. D4 denotes a distance between an end of the second portion on the side of the active region and an end of the gate electrode 6 on the side of the active region in a plan view. When the first heating value on the side of the opposite region is larger than the second heating value on the side of the active region, the gate electrode 6 may be biased toward the side of the active region with respect to the first interlayer insulating film 7 such that D3>0, D4>0, and D3−D4>0 hold. Even with such a structure, the reliability of the semiconductor device when operating can be enhanced, similarly to Embodiment 1.

### Modification 2

The heating values and the dimensions of Embodiment 1 and Modification 1 may be reverse to the heating values and the dimensions described above. In other words, when the second heating value on the side of the active region is larger than the first heating value on the side of the opposite region, the dimension of the second portion of the first interlayer insulating film 7 on the side of the active region with respect to the gate electrode 6 may be larger than the dimension of the first portion of the first interlayer insulating film 7 on the side of the opposite region with respect to the gate electrode 6. Furthermore, the gate electrode 6 may be biased toward the side of the opposite region with respect to the first interlayer insulating film 7 such that D1>0, D2>0, and D2−D1>0, or D3>0, D4>0, and D4−D3>0 hold. Even with such a structure, the reliability of the semiconductor device when operating can be enhanced, similarly to Embodiment 1.

### Modification 3

Since a current normally flows through a body diode (BD) region on the side of the active region and an SBD region on the side of the opposite region during a freewheeling operation in a power semiconductor device, the semiconductor device itself generates heat due to resistive components of these currents. Thus, assuming that a resistance value of the SBD region on the side of the opposite region in the power semiconductor device is a first resistance value (R1) and a resistance value of the BD region on the side of the active region is a second resistance value (R2), D1 and D2, or D3 and D4 may be set according to the first resistance value (R1) and the second resistance value (R2).

In other words, when the first resistance value (R1) on the side of the opposite region is larger than the second resistance value (R2) on the side of the active region, the dimension of the first portion of the first interlayer insulating film 7 on the side of the opposite region with respect to the gate electrode 6 may be larger than the dimension of the second portion of the first interlayer insulating film 7 on the side of the active region with respect to the gate electrode 6. Furthermore, the gate electrode 6 may be biased toward the side of the active region with respect to the first interlayer insulating film 7 such that D1>0, D2>0, and D1−D2>0, or D3>0, D4>0, and D3−D4>0 hold.

Alternatively, when the second resistance value (R2) on the side of the active region is larger than the first resistance value (R1) on the side of the opposite region, the dimension of the second portion of the first interlayer insulating film 7 on the side of the active region with respect to the gate electrode 6 may be larger than the dimension of the first portion of the first interlayer insulating film 7 on the side of the opposite region with respect to the gate electrode 6. Furthermore, the gate electrode 6 may be biased toward the side of the opposite region with respect to the first interlayer insulating film 7 such that D1>0, D2>0, and D2−D1>0, or D3>0, D4>0, and D4−D3>0 hold. Even with such a structure, the reliability of the semiconductor device when operating can be enhanced, similarly to Embodiment 1.

### Modification 4

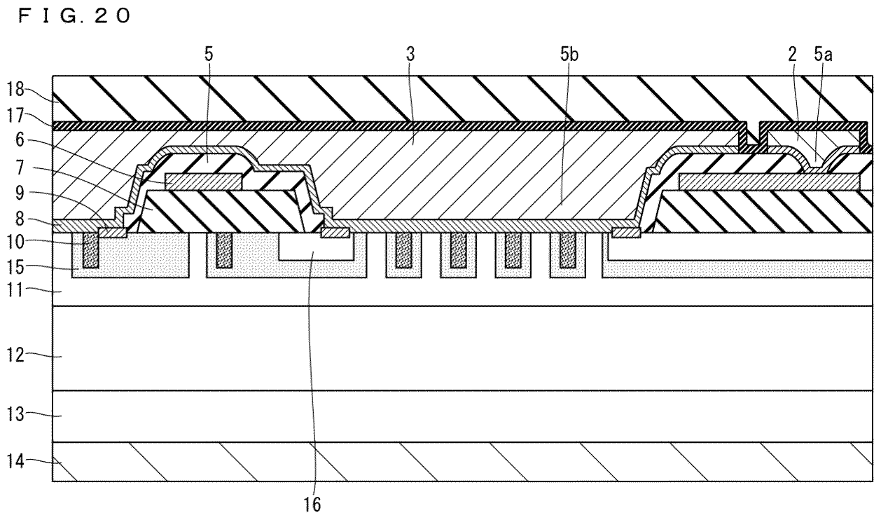

FIG. 20 is a cross-sectional schematic diagram illustrating a structure of a semiconductor device according to Modification 4 of Embodiment 1. As illustrated in FIG. 20, a protective film including a first protective film 17 covering the source electrode 3 and the gate wire 2, and a second protective film 18 covering the first protective film 17 may be provided. Example materials of the first protective film 17 preferably include an insulating material or a semi-insulating material, for example, a spin-on glass (SOG). Example materials of the second protective film 18 preferably include an insulating material or a semi-insulating material, for example, a polyimide film.

### Modification 5

While Embodiment 1 describes the semiconductor device 1 including the SBD in the termination region, the SBD need not be provided in the termination region as long as the termination region includes a structure for allowing a current to flow during a freewheeling operation. For example, a diode, for example, a p-n diode may be provided for the termination region in place of the SBD. Modifications described above may be applied to Embodiment 2 and the following Embodiments.

### Embodiment 2

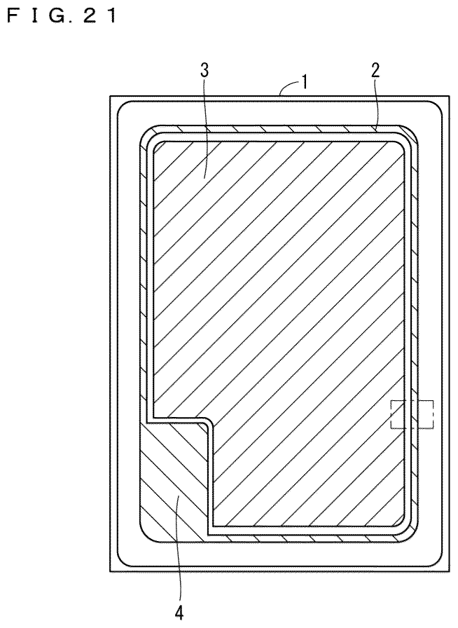

FIG. 21 is a top view illustrating a structure of the semiconductor device 1 according to Embodiment 2. On the top of the semiconductor device 1, the source electrode 3 and the gate wire 2 surrounding the source electrode 3 are provided. Furthermore, the gate pad 4 electrically continuous to the gate wire 2 is provided on a part of the upper portion of the semiconductor device 1. The gate wire 2 and the gate pad 4 are spaced and insulated from the source electrode 3.

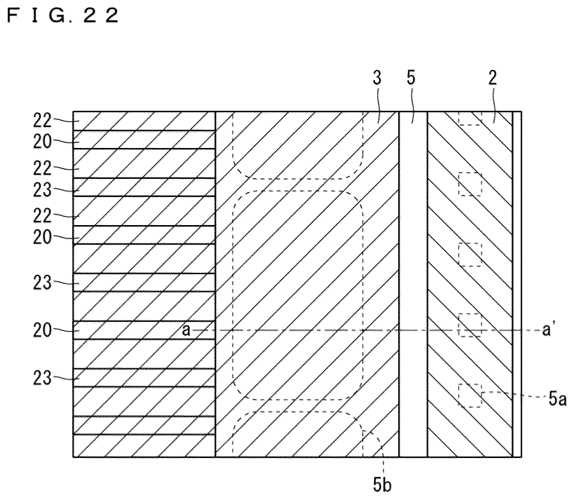

FIG. 22 is a top view illustrating an enlarged view of a portion between the active region and the termination region which is indicated by an alternate long and short dashed line in FIG. 21. In Embodiment 2, the active region includes not only the plurality of SBD regions 20 and the plurality of MOS regions 22 but also a plurality of body diode (BD) regions 23 arranged periodically in stripes. A body diode is provided for the BD regions 23. The SBD regions 20 and the BD regions 23 are alternately arranged in an example of FIG. 22. This can reduce the ON resistance in the active region.

A structure of a portion taken along an a-a′ line in the structure illustrated in FIG. 22 is identical to that of FIG. 3 described in Embodiment 1. The SBD is provided below the contact holes 5b in the termination region. Since the gate electrode 6 is biased with respect to the first interlayer insulating film 7 in Embodiment 2 similarly to Embodiment 1, damage of the gate electrode 6 in the termination region can be suppressed, and the reliability of the semiconductor device when operating can be enhanced.

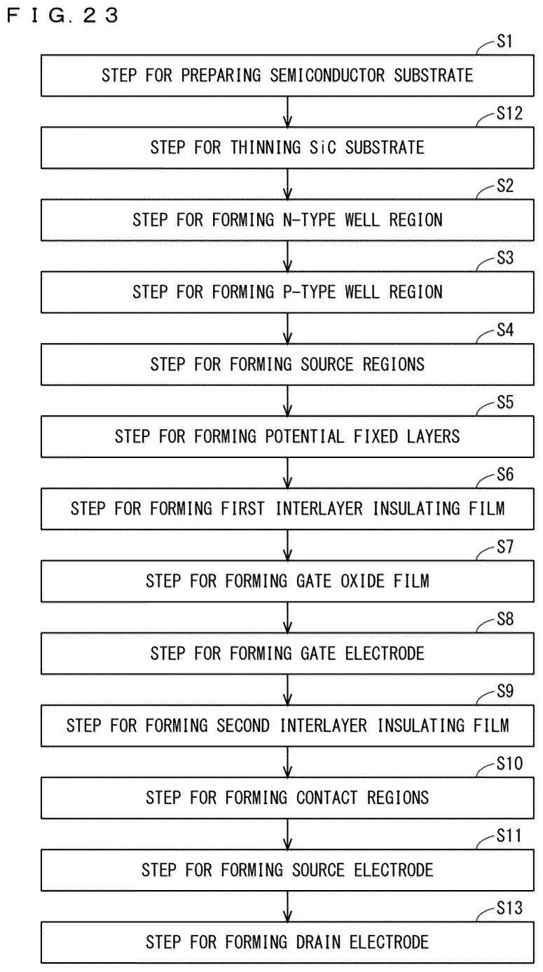

FIG. 23 is a flowchart illustrating a method of manufacturing the semiconductor device according to Embodiment 2. The method of manufacturing the semiconductor device according to Embodiment 2 is identical to a manufacturing method in which Step S12 for thinning the SiC substrate is moved next to Step S1 for preparing the semiconductor substrate in the flowchart of FIG. 4 indicating the method of manufacturing the semiconductor device according to Embodiment 1. As such, the manufacturing method may be a manufacturing method in which thinning the SiC substrate 13 is followed by Step S2 for forming the n-type well region 11 and the subsequent Steps. The semiconductor device according to Embodiment 1 may be formed in accordance with the procedure indicated by the flowchart of FIG. 23.

### Embodiment 3

A top view of a structure of a semiconductor device according to Embodiment 3 is identical to FIG. 1. On the top of the semiconductor device 1, the source electrode 3 located in the center portion, and the gate wire 2 surrounding the source electrode 3 are provided. Furthermore, the gate pad 4 is provided between the center and the end of the upper portion of the semiconductor device 1 to be electrically continuous to the gate wire 2. The gate wire 2 and the gate pad 4 are spaced and insulated from the source electrode 3.

A structure between the active region and the termination region according to Embodiment 3 is identical to the structure of the semiconductor device 1 according to Embodiment 1 which is illustrated by the top view of FIG. 2. The active region includes the SBD regions 20 provided with the SBD, and the MOS regions 22 provided with the MOSFET. As illustrated in FIG. 2, the plurality of SBD regions 20 are arranged periodically in stripes, the plurality of MOS regions 22 are arranged periodically in stripes, and the SBD regions 20 and the MOS regions 22 are alternately arranged one by one.

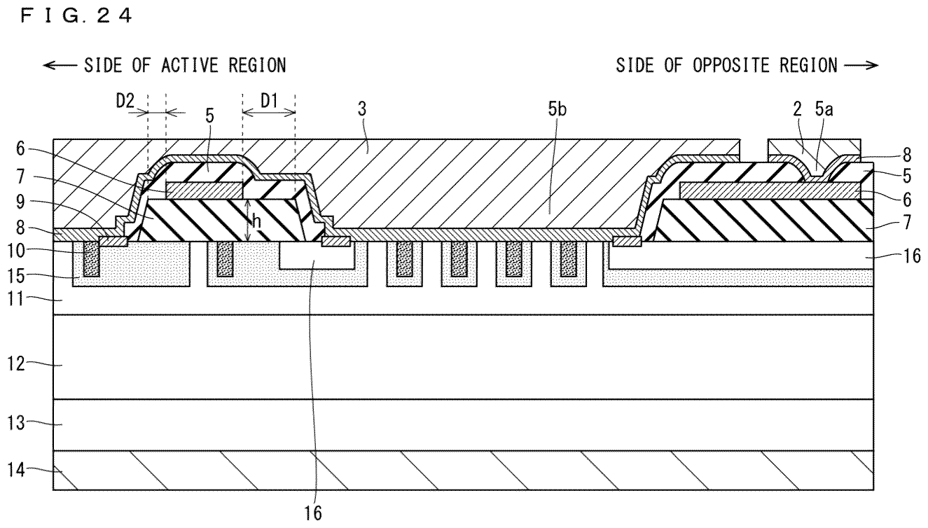

FIG. 24 is a cross-sectional schematic diagram illustrating a structure of a semiconductor device according to Embodiment 3, and is a cross-sectional schematic diagram illustrating a structure of a portion taken along the a-a′ line in FIG. 2. Since the second interlayer insulating film 5 is disposed in the termination region as described above, FIG. 24 mostly illustrates the structure of the termination region. Since the a-a′ line in FIG. 2 extends across the contact hole 5b of the second interlayer insulating film 5, FIG. 24 illustrates the second interlayer insulating film 5 in two portions that sandwich the contact hole 5b.

Here, the SBD provided for the SBD regions 20 in the active region and the SBD provided below the contact holes 5b on the side of the opposite region generate heat when operating. In Embodiment 3, the first heating value on the side of the opposite region is configured to be larger than the second heating value on the side of the active region. Each of the first heating value and the second heating value may be obtained from a conduction loss value when a semiconductor device in passing a current is in an ON state or from a switching loss value of a semiconductor device in switching between the ON state and an OFF state, as a first example of calculating the first heating value and the second heating value. As a second example, the first heating value and the second heating value may be obtained from a temperature distribution inside a semiconductor device, based on imaging using an infrared camera. The first heating value and the second heating value may be obtained from a combination of the first example and the second example, or can be calculated using various measurements or an analysis method.

When it is defined that h denotes a thickness of the first interlayer insulating film 7, D1 denotes the distance between the end of the upper portion of the first portion on the side of the opposite region and the end of the gate electrode 6 on the side of the opposite region, and D2 denotes the distance between the end of the upper portion of the second portion on the side of the active region and the end of the gate electrode 6 on the side of the active region in Embodiment 3, D1>0, D2>0, D1−D2>0, and h>min (D1, D2) hold. A value of min (D1, D2) is a smaller value of D1 and D2. Here, min (D1, D2)=D2 holds because of D1−D2>0.

### Manufacturing Method

The semiconductor device according to Embodiment 3 is manufactured by, for example, the flowchart in FIG. 4. Since Steps in Embodiment 3 are almost common to those of Embodiment 1, the detailed description is omitted herein. When an insulating film to be the first interlayer insulating film 7 is formed in CVD in Step S6 for forming the first interlayer insulating film, the insulating film with the thickness h that is greater than a smaller one of the dimension of the first portion and the dimension of the second portion is formed in Embodiment 3.

### Summary of Embodiment 3

Since the thickness h of the first interlayer insulating film 7 is greater than a smaller one of the dimension of the first portion and the dimension of the second portion in Embodiment 3, the thermal stresses applied to the gate electrode 6 can be shared not only by the gate electrode 6 but also by the first interlayer insulating film 7. This leads to reduction of the thermal stresses applied to the gate electrode 6, that is, suppression of the damage of the gate electrode 6. Thus, the reliability of the semiconductor device when operating can be enhanced. When the thickness of the first interlayer insulating film 7 is made greater than both the dimension of the first portion and the dimension of the second portion, the thermal stresses applied from the surroundings to both ends of the gate electrode 6 can be reduced, which is more suitable.

### Embodiment 4

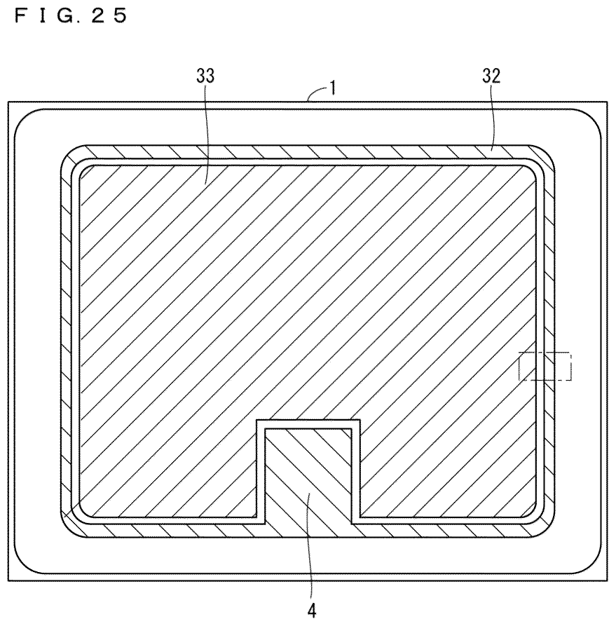

FIG. 25 is a top view illustrating a structure of a semiconductor device according to Embodiment 4. In Embodiment 4, a second gate wire 32 is disposed on the gate wire 2, and a second source electrode 33 is disposed on the source electrode 3. The second gate wire 32 and the second source electrode 33 in FIG. 25 have approximately the same shapes as those of the gate wire 2 and the source electrode 3, respectively, in FIG. 1.

A structure between the active region and the termination region according to Embodiment 4 is identical to the structure of the semiconductor device 1 according to Embodiment 1 which is illustrated by the top view of FIG. 2. The active region includes the SBD regions 20 provided with the SBD, and the MOS regions 22 provided with the MOSFET. As illustrated in FIG. 2, the plurality of SBD regions 20 are arranged periodically in stripes, the plurality of MOS regions 22 are arranged periodically in stripes, and the SBD regions 20 and the MOS regions 22 are alternately arranged one by one.

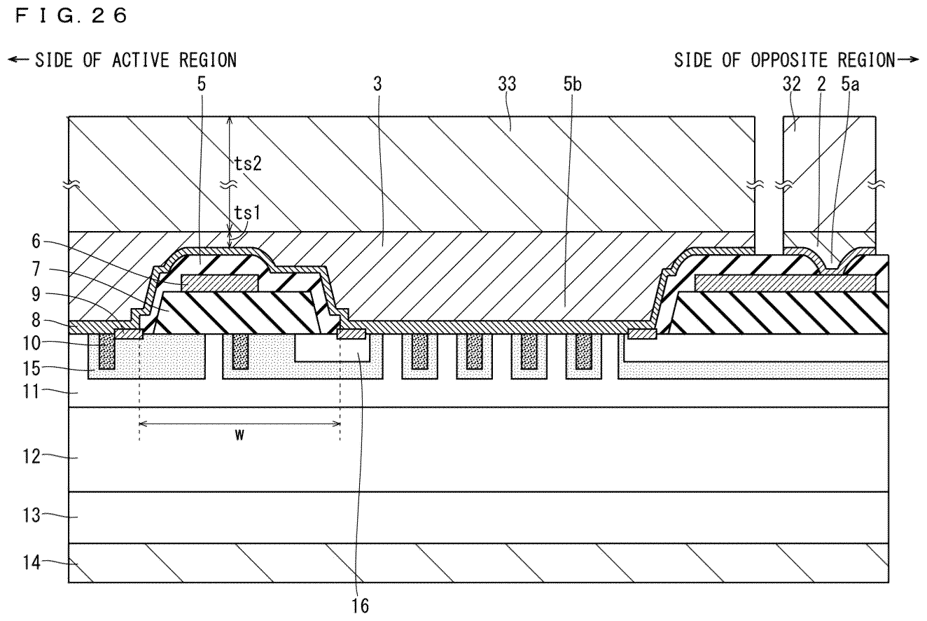

FIG. 26 is a cross-sectional schematic diagram illustrating a structure of the semiconductor device according to Embodiment 4, and is a cross-sectional schematic diagram illustrating a structure of a portion taken along the a-a′ line in FIG. 2. Since the second interlayer insulating film 5 is disposed in the termination region as described above, FIG. 26 mostly illustrates the structure of the termination region. Since the a-a′ line in FIG. 2 extends across the contact hole 5b of the second interlayer insulating film 5, FIG. 26 illustrates the second interlayer insulating film 5 in two portions that sandwich the contact hole 5b.

Here, the SBD provided for the SBD regions 20 in the active region and the SBD provided below the contact holes 5b on the side of the opposite region generate heat when operating. In Embodiment 4, the first heating value on the side of the opposite region is configured to be larger than the second heating value on the side of the active region.

In Embodiment 4, the source electrode 3 that is a first electrode as in Embodiment 1 covers the second interlayer insulating film 5. In Embodiment 4, the second gate wire 32 is disposed on the gate wire 2, and the second source electrode 33 that is a second electrode is disposed on the source electrode 3. A thermal conductivity of the second source electrode 33 is higher than a thermal conductivity of a semiconductor layer on top of which the first interlayer insulating film 7 is disposed. Here, the semiconductor layer includes, for example, at least one of the SiC substrate 13, the epitaxial growth layer 12, the n-type well region 11, the p-type well region 15, the potential fixed layers 10, or the source regions 16.

When it is defined that D1 denotes the distance between the end of the upper portion of the first portion on the side of the opposite region and the end of the gate electrode 6 on the side of the opposite region, D2 denotes the distance between the end of the upper portion of the second portion on the side of the active region and the end of the gate electrode 6 on the side of the active region, w denotes a width of the second interlayer insulating film 5, ts1 denotes a thickness of a portion of the source electrode 3 above the gate electrode 6, and ts2 denotes a thickness of a portion of the second source electrode 33 above the gate electrode 6, D1>0, D2>0, D1−D2>0, and ts2>w>ts1 hold.

### Manufacturing Method

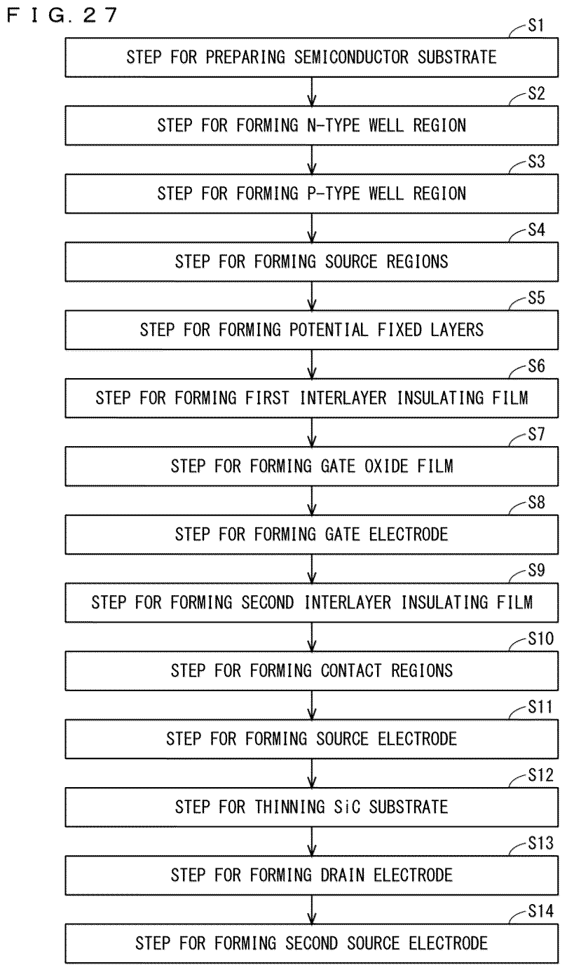

FIG. 27 is a flowchart illustrating a method of manufacturing the semiconductor device according to Embodiment 4. The manufacturing method in FIG. 27 is identical to a manufacturing method in which Step S14 for forming the second source electrode has been added subsequent to Step S13 for forming the drain electrode, to the manufacturing method in FIG. 4. Thus, Step S14 for forming the second source electrode will be mainly described hereinafter.

In Step S14 for forming the second source electrode, a conductive film to be the second source electrode 33 is formed and patterned. A material higher in thermal conductivity than those for the source electrode 3 and the aforementioned semiconductor layer is used for the second source electrode 33. When, for example, one of an aluminum alloy of aluminum and silicon, or nickel is deposited as the source electrode 3, depositing, for example, copper, silver, or gold as the second source electrode 33 is suitable. Depositing copper and an alloy mainly containing copper as the second source electrode 33 is desirable in view of economy. A method of forming the second source electrode 33 may be PVD or plating. For example, sputtering is used as the PVD, and electroplating or electroless plating is used as the plating.

An example of forming the second source electrode 33 using electroless plating will be hereinafter described. Before forming the second source electrode 33 on the source electrode 3, the front surface of the source electrode 3 is cleaned to remove, for example, an oxide film, organic matters, and a foreign substance. For example, acid cleaning or plasma treatment is used for the cleaning.

Since a material of the source electrode 3 is a metal whose main component is aluminum, for example, aluminum, an aluminum-silicon alloy, or an aluminum-copper alloy, it is difficult to perform electroless plating of copper as it is. Thus, the source electrode 3 is immersed in a zincate bath to perform a zincate process of replacing aluminum with zinc in the source electrode 3, which replaces the front surface of the source electrode 3 with zinc. Then, an electroless plating process using a copper sulfate bath held at approximately 60 to 80° C. can easily form the second source electrode 33. While formation of the second source electrode 33 is described above, the second gate wire 32 is formed in a similar manner.

### Summary of Embodiment 4

In Embodiment 4, the thickness ts2 of the portion of the second source electrode 33 above the gate electrode 6 is greater than the width w of the second interlayer insulating film 5, the width w of the second interlayer insulating film 5 is greater than the thickness tsl of the portion of the source electrode 3 above the gate electrode 6, and the thermal conductivity of the second source electrode 33 is higher than the thermal conductivity of the semiconductor layer.

In such a structure, the thermal capacity of the second source electrode 33 can not only suppress an increase in the heat generated in the semiconductor device through passage of a current and in temperature of the semiconductor device, but also can transfer the heat to the outside through the second source electrode 33. This reduces the thermal stresses applied to the gate electrode 6 and suppresses the damage of the gate electrode 6. Thus, the reliability of the semiconductor device when operating can be enhanced. When a difference in thermal expansion coefficient between the second source electrode 33 and the gate electrode 6 is smaller than a difference in thermal expansion coefficient between the source electrode 3 and the gate electrode 6, the thermal stresses applied to the gate electrode 6 can further be reduced, which is more suitable. The details of Embodiment 4 may be applied to, for example, Modification 2 of Embodiment 1.

### Modification 1

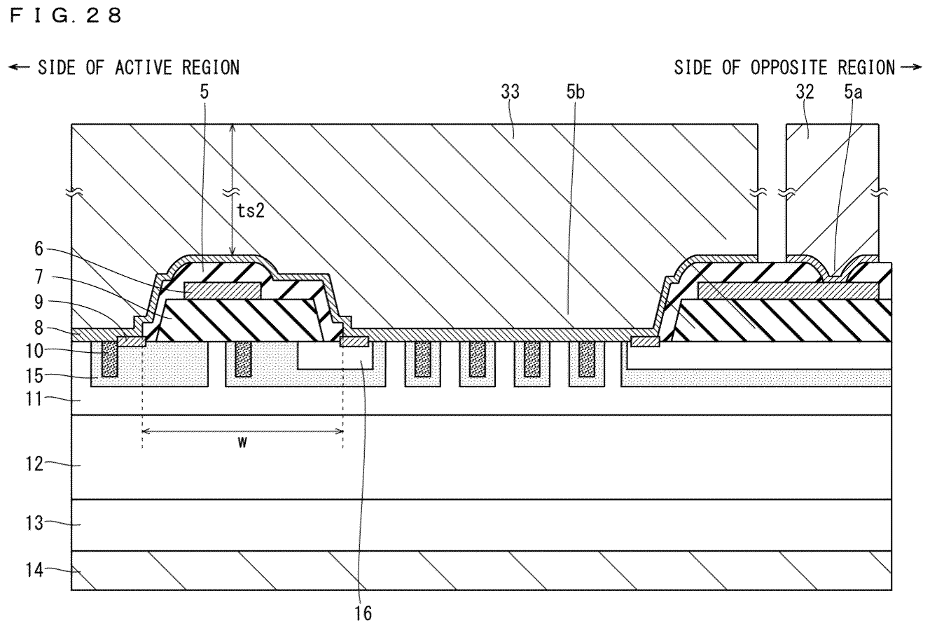

FIG. 28 is a cross-sectional schematic diagram illustrating a structure of a semiconductor device according to Modification 1 of Embodiment 4. In this Modification 1, the gate wire 2 and the source electrode 3 are omitted, and the second gate wire 32 and the second source electrode 33 are directly connected to the barrier metal layer 8. Since such a structure can form the second gate wire 32 and the second source electrode 33 in PVD or plating while omitting Step S11 for forming the source electrode in the flowchart of FIG. 27, the manufacturing steps can be simplified.

In this Modification 1, the thickness ts2 of the portion of the second source electrode 33 above the gate electrode 6 is greater than the width w of the second interlayer insulating film 5, and the thermal conductivity of the second source electrode 33 is higher than the thermal conductivity of the semiconductor layer. In such a structure, the heat generated in the semiconductor device through passage of a current can be transferred to the outside through the second source electrode 33. This reduces the thermal stresses applied to the gate electrode 6 and suppresses the damage of the gate electrode 6. Thus, the reliability of the semiconductor device when operating can be enhanced.

### Embodiment 5

Embodiment 5 will describe a power conversion device to which the semiconductor devices according to Embodiments 1 to 4 are applied. Although the present disclosure is not limited to specific power conversion devices, Embodiment 5 will describe application of the present disclosure to a three-phase inverter.

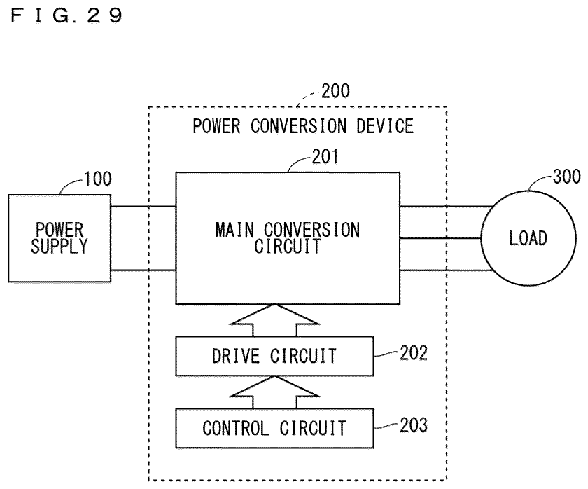

FIG. 29 is a block diagram illustrating a configuration of a power conversion system to which a power conversion device 200 according to Embodiment 5 is applied. The power conversion system illustrated in FIG. 29 includes a power supply 100, the power conversion device 200, and a load 300. The power supply 100, which is a DC power supply, supplies a DC power to the power conversion device 200. The power supply 100 may include various components such as a DC system, a solar battery, and a rechargeable battery, a rectifying circuit connected to an AC system, or an AC/DC converter. The power supply 100 may include a DC/DC converter which converts the DC power output from a DC system into a predefined power.

The power conversion device 200 is a three-phase inverter connected between the power supply 100 and the load 300. The power conversion device 200 converts the DC power supplied from the power supply 100 into the AC power to supply the AC power to the load 300. As illustrated in FIG. 29, the power conversion device 200 includes a main conversion circuit 201 that converts the DC power to output the AC power, a drive circuit 202 that outputs a driving signal for driving each switching device in the main conversion circuit 201, and a control circuit 203 that outputs, to the drive circuit 202, a control signal for controlling the drive circuit 202.

The load 300 is a three-phase electrical motor driven by the AC power supplied from the power conversion device 200. The load 300 is not limited to specific use but is an electrical motor mounted on various types of electrical devices. Thus, the load 300 is used as an electrical motor for, for example, a hybrid car, an electrical car, a rail vehicle, an elevator, or air-conditioning equipment.

The power conversion device 200 will be described in detail hereinafter. The main conversion circuit 201 includes the switching devices and freewheeling diodes (not illustrated). Switching of the switching devices allows the main conversion circuit 201 to convert the DC power supplied from the power supply 100 into the AC power and supply the AC power to the load 300. The specific circuit configuration of the main conversion circuit 201 is of various types. The main conversion circuit 201 according to Embodiment 5 is a three-phase full-bridge circuit having two levels, and includes six switching devices and six freewheeling diodes anti-parallel connected to the respective switching devices. The semiconductor device 1 according to one of Embodiments 1 to 4 and its Modifications is applied as at least one of the switching devices and the freewheeling diodes of the main conversion circuit 201. The six switching devices form pairs of upper and lower arms in each pair of which the two switching devices are serially connected to each other. The pairs of upper and lower arms form the respective phases (U-phase, V-phase, and W-phase) of the full-bridge circuit. Output terminals of the respective pairs of upper and lower arms, i.e., three output terminals of the main conversion circuit 201 are connected to the load 300.

The drive circuit 202 generates driving signals for driving the switching devices of the main conversion circuit 201, and provides the driving signals to control electrodes of the switching devices of the main conversion circuit 201. Specifically, the drive circuit 202 outputs the driving signal for switching each of the switching devices to an ON state and the driving signal for switching the switching device to an OFF state, to a control electrode of the switching device in accordance with the control signal from the control circuit 203 to be described later. When the switching device is kept in the ON state, the driving signal is a voltage signal (ON signal) higher than or equal to a threshold voltage of the switching device. When the switching device is kept in the OFF state, the driving signal is a voltage signal (OFF signal) lower than the threshold voltage of the switching device.

The control circuit 203 controls the switching devices of the main conversion circuit 201 to supply a desired power to the load 300. Specifically, the control circuit 203 calculates a time (ON time) when each of the switching devices of the main conversion circuit 201 needs to enter the ON state, based on the power which needs to be supplied to the load 300. For example, the control circuit 203 calculates the time so that the main conversion circuit 201 can be controlled by pulse width modulation (PWM) control for modulating the ON time of the switching devices in accordance with the voltage which needs to be output. Then, the control circuit 203 outputs a control instruction (a control signal) to the drive circuit 202 so that the drive circuit 202 outputs the ON signal to the switching device which needs to enter the ON state and outputs the OFF signal to the switching device which needs to enter the OFF state at each time. The drive circuit 202 outputs the ON signal or the OFF signal as the driving signal to the control electrode of each of the switching devices in accordance with this control signal.

A method of manufacturing the power conversion device 200 includes the following steps. The semiconductor device 1 is manufactured by the manufacturing method described in Embodiments or its Modifications above. The main conversion circuit 201 including the semiconductor device 1 is formed, and the drive circuit 202 and the control circuit 203 are formed. This produces the power conversion device 200. When the main conversion circuit 201 is formed, the drain electrode of the semiconductor device 1 is bonded to a mounting substrate, and the source electrode of the semiconductor device 1 is bonded to the mounting substrate through a wire.

Since the semiconductor devices according to Embodiments 1 to 4 are used as the semiconductor devices included in the main conversion circuit 201 in the power conversion device according to Embodiment 5, the reliability of the main conversion circuit 201 and the power conversion device when operating can be enhanced.

While Embodiment 5 describes the example of applying the present disclosure to the three-phase inverter having the two levels, the present disclosure is not limited thereto, but is applicable to various power conversion devices. While the power conversion device according to Embodiment 5 is the power conversion device having the two levels, the power conversion device may have three or multiple levels. The present disclosure may be applied to a single-phase inverter when the power is supplied to a single-phase load. Furthermore, the present disclosure is also applicable to a DC/DC converter or an AC/DC converter when the power is supplied to, for example, a DC load.

The load of the power conversion device to which the present disclosure is applied is not limited to the electrical motor as described above. The power conversion device can also be used as a power-supply device of, for example, an electrical discharge machine, a laser beam machine, an induction heat cooking device, or a non-contact power feeding system, and can be further used as a power conditioner of, for example, a solar power system or an electricity storage system.

Embodiments (and Modifications) can be freely combined, or appropriately modified and omitted.

A summary of various aspects of the present disclosure will be hereinafter described as Appendixes.

### [Appendix 1]

A semiconductor device in which an active region and a termination region are defined, the semiconductor device comprising:
a first interlayer insulating film provided in the termination region; and
a gate electrode provided on the first interlayer insulating film,
wherein a dimension of a first portion of the first interlayer insulating film on a side of an opposite region with respect to the gate electrode is larger than a dimension of a second portion of the first interlayer insulating film on a side of the active region with respect to the gate electrode when a first heating value on the side of the opposite region is larger than a second heating value on the side of the active region, the opposite region being located opposite to the active region with respect to the gate electrode, and
the dimension of the second portion is larger than the dimension of the first portion when the second heating value is larger than the first heating value.

### [Appendix 2]

The semiconductor device according to appendix 1,
wherein assuming that D1 denotes a distance between an end of an upper portion of the first portion on the side of the opposite region and an end of the gate electrode on the side of the opposite region, and D2 denotes a distance between an end of an upper portion of the second portion on the side of the active region and an end of the gate electrode on the side of the active region,
D1>0, D2>0, and D1−D2>0 hold when the first heating value is larger than the second heating value, and
D1>0, D2>0, and D2−D1>0 hold when the second heating value is larger than the first heating value.

### [Appendix 3]

The semiconductor device according to appendix 1,
wherein assuming that in a plan view, D3 denotes a distance between an end of the first portion on the side of the opposite region and an end of the gate electrode on the side of the opposite region, and D4 denotes a distance between an end of the second portion on the side of the active region and an end of the gate electrode on the side of the active region,
D3>0, D4>0, and D3−D4>0 hold when the first heating value is larger than the second heating value, and
D3>0, D4>0, and D4−D3>0 hold when the second heating value is larger than the first heating value.

### [Appendix 4]

A semiconductor device in which an active region and a termination region are defined, the semiconductor device comprising:
a first interlayer insulating film provided in the termination region; and
a gate electrode provided on the first interlayer insulating film,
wherein a dimension of a first portion of the first interlayer insulating film on a side of an opposite region with respect to the gate electrode is larger than a dimension of a second portion of the first interlayer insulating film on a side of the active region with respect to the gate electrode when a first resistance value of a Schottky barrier diode region on the side of the opposite region is larger than a second resistance value of a body diode region on the side of the active region, the opposite region being located opposite to the active region with respect to the gate electrode, and
the dimension of the second portion is larger than the dimension of the first portion when the second resistance value is larger than the first resistance value.

### [Appendix 5]

The semiconductor device according to appendix 4,
wherein when D1 denotes a distance between an end of an upper portion of the first portion on the side of the opposite region and an end of the gate electrode on the side of the opposite region, and D2 denotes a distance between an end of an upper portion of the second portion on the side of the active region and an end of the gate electrode on the side of the active region,
D1>0, D2>0, and D1−D2>0 hold when the first resistance value is larger than the second resistance value, and
D1>0, D2>0, and D2−D1>0 hold when the second resistance value is larger than the first resistance value.

### [Appendix 6]

The semiconductor device according to appendix 4,
wherein assuming that in a plan view, D3 denotes a distance between an end of the first portion on the side of the opposite region and an end of the gate electrode on the side of the opposite region, and D4 denotes a distance between an end of the second portion on the side of the active region and an end of the gate electrode on the side of the active region,
D3>0, D4>0, and D3−D4>0 hold when the first resistance value is larger than the second resistance value, and
D3>0, D4>0, and D4−D3>0 hold when the second resistance value is larger than the first resistance value.

### [Appendix 7]

The semiconductor device according to any one of appendixes 1 to 6,
wherein the active region includes a Schottky barrier diode region.

### [Appendix 8]

The semiconductor device according to any one of appendixes 1 to 6,
wherein the active region includes:
a plurality of Schottky barrier diode regions arranged periodically in stripes; and
a plurality of metal-oxide semiconductor regions arranged periodically in stripes.

### [Appendix 9]

The semiconductor device according to appendix 8,
wherein the active region further includes a plurality of body diode regions arranged periodically in stripes.

### [Appendix 10]

The semiconductor device according to any one of appendixes 1 to 9,
wherein a thickness of the first interlayer insulating film is greater than a smaller one of the dimension of the first portion and the dimension of the second portion.

### [Appendix 11]

The semiconductor device according to any one of appendixes 1 to 10, further comprising:
a second interlayer insulating film covering the first interlayer insulating film and the gate electrode;
a first electrode covering the second interlayer insulating film; and
a second electrode covering the first electrode,
wherein a thermal conductivity of the second electrode is higher than a thermal conductivity of a semiconductor layer on top of which the first interlayer insulating film is disposed,
a thickness of a portion of the second electrode above the gate electrode is greater than a width of the second interlayer insulating film, and
the width of the second interlayer insulating film is greater than a thickness of a portion of the first electrode above the gate electrode.

### [Appendix 12]

The semiconductor device according to appendix 11,
wherein a difference in thermal expansion coefficient between the second electrode and the gate electrode is smaller than a difference in thermal expansion coefficient between the first electrode and the gate electrode.

### [Appendix 13]

A power conversion device, comprising:
a main conversion circuit including the semiconductor device according to any one of appendixes 1 to 12, the main conversion circuit converting an input power to output a resulting power;
a drive circuit outputting, to the semiconductor device, a driving signal for driving the semiconductor device; and
a control circuit outputting, to the drive circuit, a control signal for controlling the drive circuit.

### EXPLANATION OF REFERENCE SIGNS

1 semiconductor device, 3 source electrode, 5 second interlayer insulating film, 6 gate electrode, 7 first interlayer insulating film, 20 SBD region, 22 MOS region, 23 BD region, 33 second source electrode, 200 power conversion device, 201 main conversion circuit, 202 drive circuit, 203 control circuit.

1. A semiconductor device in which an active region and a termination region are defined, the semiconductor device comprising:
a first interlayer insulating film provided in the termination region; and
a gate electrode provided on the first interlayer insulating film,
wherein a dimension of a first portion of the first interlayer insulating film on a side of an opposite region with respect to the gate electrode is larger than a dimension of a second portion of the first interlayer insulating film on a side of the active region with respect to the gate electrode when a first heating value on the side of the opposite region is larger than a second heating value on the side of the active region, the opposite region being located opposite to the active region with respect to the gate electrode, and
the dimension of the second portion is larger than the dimension of the first portion when the second heating value is larger than the first heating value.

2. The semiconductor device according to claim 1,
wherein assuming that D1 denotes a distance between an end of an upper portion of the first portion on the side of the opposite region and an end of the gate electrode on the side of the opposite region, and D2 denotes a distance between an end of an upper portion of the second portion on the side of the active region and an end of the gate electrode on the side of the active region,
D1>0, D2>0, and D1−D2>0 hold when the first heating value is larger than the second heating value, and
D1>0, D2>0, and D2−D1>0 hold when the second heating value is larger than the first heating value.

3. The semiconductor device according to claim 1,
wherein assuming that in a plan view, D3 denotes a distance between an end of the first portion on the side of the opposite region and an end of the gate electrode on the side of the opposite region, and D4 denotes a distance between an end of the second portion on the side of the active region and an end of the gate electrode on the side of the active region,
D3>0, D4>0, and D3−D4>0 hold when the first heating value is larger than the second heating value, and
D3>0, D4>0, and D4−D3>0 hold when the second heating value is larger than the first heating value.

4. A semiconductor device in which an active region and a termination region are defined, the semiconductor device comprising:
a first interlayer insulating film provided in the termination region; and
a gate electrode provided on the first interlayer insulating film,
wherein a dimension of a first portion of the first interlayer insulating film on a side of an opposite region with respect to the gate electrode is larger than a dimension of a second portion of the first interlayer insulating film on a side of the active region with respect to the gate electrode when a first resistance value of a Schottky barrier diode region on the side of the opposite region is larger than a second resistance value of a body diode region on the side of the active region, the opposite region being located opposite to the active region with respect to the gate electrode, and
the dimension of the second portion is larger than the dimension of the first portion when the second resistance value is larger than the first resistance value.

5. The semiconductor device according to claim 4,
wherein when D1 denotes a distance between an end of an upper portion of the first portion on the side of the opposite region and an end of the gate electrode on the side of the opposite region, and D2 denotes a distance between an end of an upper portion of the second portion on the side of the active region and an end of the gate electrode on the side of the active region,
D1>0, D2>0, and D1−D2>0 hold when the first resistance value is larger than the second resistance value, and
D1>0, D2>0, and D2−D1>0 hold when the second resistance value is larger than the first resistance value.

6. The semiconductor device according to claim 4,
wherein assuming that in a plan view, D3 denotes a distance between an end of the first portion on the side of the opposite region and an end of the gate electrode on the side of the opposite region, and D4 denotes a distance between an end of the second portion on the side of the active region and an end of the gate electrode on the side of the active region,
D3>0, D4>0, and D3−D4>0 hold when the first resistance value is larger than the second resistance value, and
D3>0, D4>0, and D4−D3>0 hold when the second resistance value is larger than the first resistance value.

7. The semiconductor device according to claim 1,
wherein the active region includes a Schottky barrier diode region.

8. The semiconductor device according to claim 1,
wherein the active region includes:
a plurality of Schottky barrier diode regions arranged periodically in stripes; and
a plurality of metal-oxide semiconductor regions arranged periodically in stripes.

9. The semiconductor device according to claim 8,
wherein the active region further includes a plurality of body diode regions arranged periodically in stripes.

10. The semiconductor device according to claim 1,
wherein a thickness of the first interlayer insulating film is greater than a smaller one of the dimension of the first portion and the dimension of the second portion.

11. The semiconductor device according to claim 1, further comprising:
a second interlayer insulating film covering the first interlayer insulating film and the gate electrode;
a first electrode covering the second interlayer insulating film; and
a second electrode covering the first electrode,
wherein a thermal conductivity of the second electrode is higher than a thermal conductivity of a semiconductor layer on top of which the first interlayer insulating film is disposed,
a thickness of a portion of the second electrode above the gate electrode is greater than a width of the second interlayer insulating film, and
the width of the second interlayer insulating film is greater than a thickness of a portion of the first electrode above the gate electrode.

12. The semiconductor device according to claim 11,
wherein a difference in thermal expansion coefficient between the second electrode and the gate electrode is smaller than a difference in thermal expansion coefficient between the first electrode and the gate electrode.

13. A power conversion device, comprising:
a main conversion circuit including the semiconductor device according to claim 1, the main conversion circuit converting an input power to output a resulting power;
a drive circuit outputting, to the semiconductor device, a driving signal for driving the semiconductor device; and
a control circuit outputting, to the drive circuit, a control signal for controlling the drive circuit.

14. A power conversion device, comprising:
a main conversion circuit including the semiconductor device according to claim 4, the main conversion circuit converting an input power to output a resulting power;
a drive circuit outputting, to the semiconductor device, a driving signal for driving the semiconductor device; and
a control circuit outputting, to the drive circuit, a control signal for controlling the drive circuit.
